(19) United States
(12) Patent Application Publication
(10) Pub. No.: US 2003/0029493 A1
(43) Pub. Date: Feb. 13, 2003

(54) Method for producing photovoltaic thin film module

(76) Inventor: Albert Plessing, Brunn (AT)

Correspondence Address: YOUNG & THOMPSON, 745 SOUTH 23RD STREET 2ND FLOOR, ARLINGTON, VA, 22202

(21) Appl. No.: 10/221,028

(22) PCT Filed: Mar. 5, 2001
(86) PCT No.: PCT/AT01/00061

(30) Foreign Application Priority Data
Mar. 9, 2000 (AT) A 0387/2000
Oct. 5, 2000 (AT) A 1698/2000

(51) Int. Cl. H01L 25/00

(52) U.S. Cl. 136/251; 438/64

(57) ABSTRACT

The invention relates to a method for producing a photovoltaic thin film module (1) which is provided with a thin film solar cell system (2) that is mounted on carrier materials (3) and is covered with a compound (4) on at least one side of the surface, whereby said compound consists of an encapsulating material and is provided with a sealing layer (5) on the side of the surface thereof, said side being arranged on the thin film solar cell system (2). According to a covering method, the encapsulating material (4) and the thin film solar cell system (2), together with the carrier (3), are guided along one another and are pressed under pressure and at an increased temperature in such a way that a weather-proof, photovoltaic thin film module in the form of a compound (1) is designed. According to a method that can be carried out easily, a photovoltaic thin film module that is resistant to UV light, water vapour and other effects of the weather is provided. The photovoltaic module can additionally be provided with flexible characteristics by selecting the carrier material in such a way that said material is configured in the form of plastic foils or plastic foil compounds for instance.

The invention relates to a process for producing a photovoltaic thin film module which has a thin film solar cell system which has been applied to carrier materials and which is optionally jacketed on both sides by encapsulation material composites.

### PRIOR ART

Photovoltaic cells are used to produce electrical energy from sunlight. Energy is produced by the solar cell system which is preferably made by thin film solar cells. Thin film solar cells can be built from various semiconductor systems, such as CIGS (copper-indium-gallium-selenide), CTS (cadmium-tellurium-sulfide), a-Si (amorphous silicon) and others.

These thin semiconductor systems are applied to stiff carrier materials such as glass or to flexible carrier materials such as polyimide films, steel strips, metal foils and the like.

Thin film solar cells are sensitive to environmental effects such as moisture, oxygen and UV light. But they must also be protected against mechanical damage and in addition must be electrically insulated. Therefore it is necessary to jacket the thin film solar cells on both sides with encapsulation materials. Encapsulation materials can be for example one or more layers of glass and/or plastic films.

Film composites consisting essentially of polyvinyl fluoride (PVF) and polyethylene terephthalate (PETP) are marketed by the applicant under the name ICOSOLAR and are used to produce photovoltaic modules in the vacuum lamination process disclosed according to WO-A1-94/29106. This known process does make available photovoltaic modules in which the solar cell system is satisfactorily protected against environmental effects, but the process itself is associated with relatively high energy consumption and long process times.

### DESCRIPTION OF THE INVENTION

The object of this invention is therefore to devise a process for producing photovoltaic modules which can be carried out with reduced process duration and low energy cost and photovoltaic modules with satisfactory weather resistance for outside application are prepared.

As claimed in the invention a process of the initially mentioned type is proposed which is characterized in that in a lamination step the material web for the encapsulation material composite consisting of a protective layer and a sealing layer, and another material web for the thin film solar cell system and its carrier material are brought near one another in a lamination station such that the sealing layer adjoins the thin film solar cell system and by using increased pressure and optionally increased temperature in the lamination station a composite for a photovoltaic thin film module is formed.

Advantageous embodiments of the process as claimed in the invention are the subject matter of the dependent claims.

### DESCRIPTION OF THE INVENTION USING DRAWINGS AND EMBODIMENTS

Embodiments of the invention are now detailed using the drawings as shown in FIGS. 1 to 5.

FIG. 1 shows the structure of a photovoltaic module 1 produced using the process as claimed in the invention with increased stiffness, which consists of the thin film solar cell system 2 on a stiff carrier material 3, for example, glass, which is used at the same time as the encapsulation material, and of a second encapsulation material 4.

The encapsulation material 4 is shown in FIG. 1a. It consists of a plastic sealing layer 5 and a barrier layer 9 which contains a carrier layer 6 for an inorganic oxide layer 7 which has been deposited from the vapor phase, and a weather protection layer 8.

FIG. 2 shows the structure of a flexible thin film module 10 produced by the process as claimed in the invention. The flexible properties are produced by the flexible carrier material 11.

FIG. 3 shows a device 12 for producing a stiff thin film module 1.

FIG. 4 shows a device 20 for producing a flexible thin film module 10.

FIG. 5 shows the water vapor permeability of several carrier films provided with a SiOx coating, different plastics being used as the carrier film and compared to one another.

### EMBODIMENTS OF THE INVENTION

The invention is now detailed using drawings and embodiments.

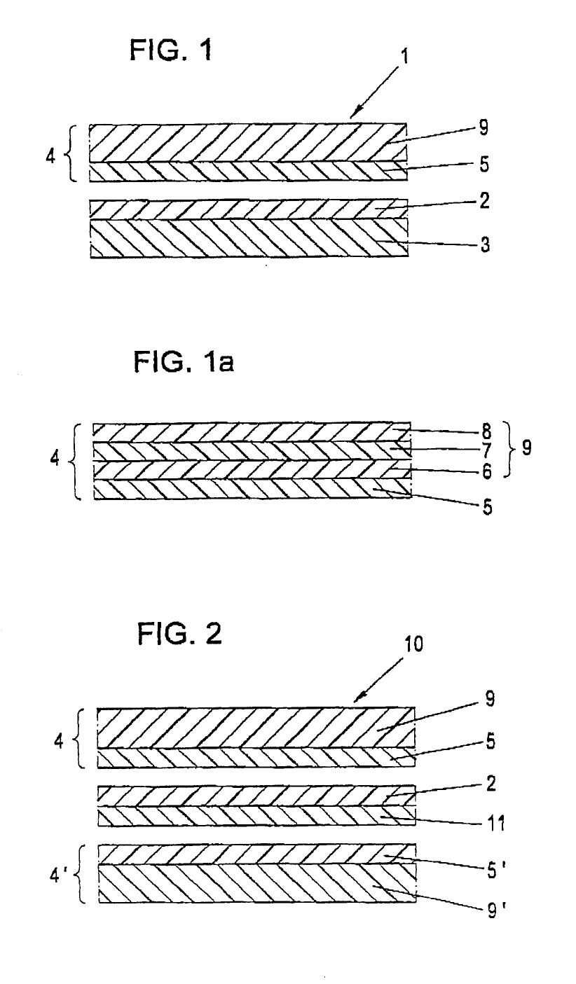

In the first process stage the encapsulation material 4 as shown in FIG. 1a consisting of the weather protection layer 8, the inorganic oxide layer 7, the carrier layer 6 and the plastic sealing layer 5 is formed.

Examples a) to c) show possible versions for the selection of materials in the respective layers:

Example a):

Weather protection layer 8: Polyvinyl chloride (PVF) or polyvinylidene chloride (PVDF) in film form,

Cement layer (not shown): Polyurethane

Inorganic oxide layer 7: Silicon oxide (SiOx) or aluminum oxide (Al₂O₃)

Carrier layer 6 for the inorganic oxide layer 7: Polyethylene naphthenate (PEN) or polyethylene terephthalate (PETP) and coextrudates therefrom in the form of films or film composites

Plastic sealing layer 5: ethylene vinyl acetate (EVA) or ionomers, polymethylmethacrylate (PMMA), polyurethane, polyester or Hot Melt

Example b):

Weather protection layer 8: Top Coat coating of polyurethane or polymethylmethacrylate (PMMA) and stabilized polyethylene terephthalate film (PETP film)

Cement layer (not shown): Polyurethane

Inorganic oxide layer 7: Silicon oxide (SiOx) or aluminum oxide (Al₂O₃)

Carrier layer 6 for the inorganic oxide layer 7: Polyethylene naphthenate (PEN) or polyethylene terephthalate (PETP) and coextrudates therefrom in the form of films or film composites

Plastic sealing layer 5: ethylene vinyl acetate (EVA) or ionomers, polymethylmethacrylate (PMMA), polyurethane, polyester or Hot Melt

Example c):

Weather protection layer 8: Fluoropolymers such as ethylene-tetrafluorethyelene copolymer (ETFE), polyvinylidene fluoride (PVDF), polyvinylidene fluoride (PVF) or other fluoropolymer film

Inorganic oxide layer 7: Silicon oxide (SiOx) or aluminum oxide (Al₂O₃)

Plastic sealing layer 5: ethylene vinyl acetate (EVA) or ionomers, polymethylmethacrylate (PMMA), polyurethane, polyester or Hot Melt

In examples a) to c) the components of the encapsulation material 4 are listed; by their interaction they protect the thin film solar cell system 2 against the effects of weathering and the penetration of water vapor.

Especially fluoropolymers which protect the thin film solar cell system 2 against the effects of weathering, for example UV rays, are chosen as the weathering protective layer 8.

The inorganic oxide layer 7 in a thickness from 30 to 200 nm is applied by vapor deposition in a vacuum to the carrier layer 6 which consists for example of PEN or PET-PEN coextrudate. The barrier layer 9 consisting of the carrier layer 6 and the inorganic oxide layer 7 protects the thin film solar cell system 2 against the penetration of water vapor.

The layer structure with the inorganic oxide layer 7 has the advantage that the water vapor permeability is lower by a factor of 10 than in comparable inorganic oxide layers which are applied to PETP films; this is shown using FIG. 5. This indicates that polyethylene terephthalate (PETP) as the carrier layer 6 shows satisfactory values, but the water vapor permeability expressed in g/m² d (gram per square meter and day) can be greatly reduced by the addition of polyethylene naphthenate (PEN). This is demonstrated in FIG. 5 using the coextrudate PETP-PEN and using pure PEN based on two measurement series at a time per plastic.

The sealing layer 5 used in the encapsulation material 4 due to its adhesive properties implements an additional protection function for the thin film solar cell system 2 since the thin film solar cell system is cemented to the encapsulation material 4 via the sealing layer.

Formation of the encapsulation material 4 using the sample versions according to a) to c) with respect to selection of materials relating to the weathering layer 8, barrier layer 7, carrier layer 6 and the sealing layer 5 takes place in a known lamination process.

Regardless of this, the barrier layer 7, for example a silicon oxide (SiOx) layer, is applied to the carrier layer 6, for example a polyethylene naphthenate film (PETP film), a coextruded polyethylene terephthalate-polynaphthenate film (PETP-PEN film), by precipitation from the vapor phase.

Consequently, the weathering layer 8 which can be a plastic film or plastic film composite is laminated onto the barrier layer 7. Likewise the sealing layer 5, for example a polyurethane cement, can be applied by lamination.

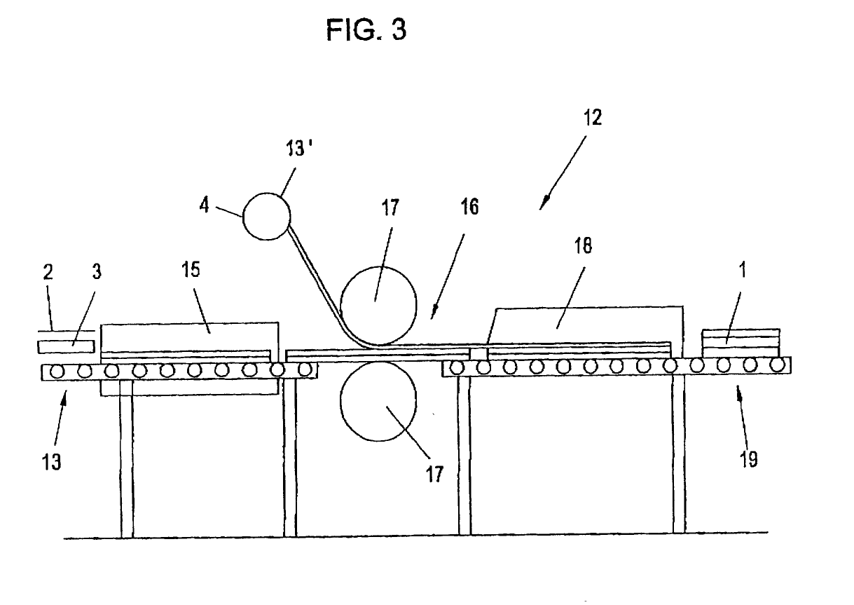

The encapsulation material 4 which is now formed is supported on the delivery roller 13′ in the device as shown in FIG. 3. In the loading station 13 the thin film solar cell system 2 together with the stiff carrier material 3, for example glass, is applied to the transport belt (not shown) and supplied to the heating station 15. By means of control devices (not shown) in the heating station the thin film solar cell system 2 together with the rigid carrier material 3, for example the glass carrier, is preheated to the softening point of the sealing layer 5 in the encapsulation material 4. Both the preheated encapsulation material 4 and also the thin film solar cell system 2 preheated to temperatures from 70 to 180° C. together with the glass carrier 3 are now supplied to the lamination station 16 in the form of a calender roller pair 17. Due to the increased temperature in the lamination station 16 which is preferably in the range from 70 to 180° C., and the pressure which is exerted by the calender rollers 17 and which is preferably 80 to 400 N/cm (line pressure), the encapsulated photovoltaic module 1 as shown in FIG. 1 is formed by lamination. It is transferred to a hardening oven (18) in which the hardening, especially of the sealing layer 5, takes place at temperatures of roughly 120 to 190° C. After corresponding cropping, the completed thin film module 1 is removed at the discharge station 19.

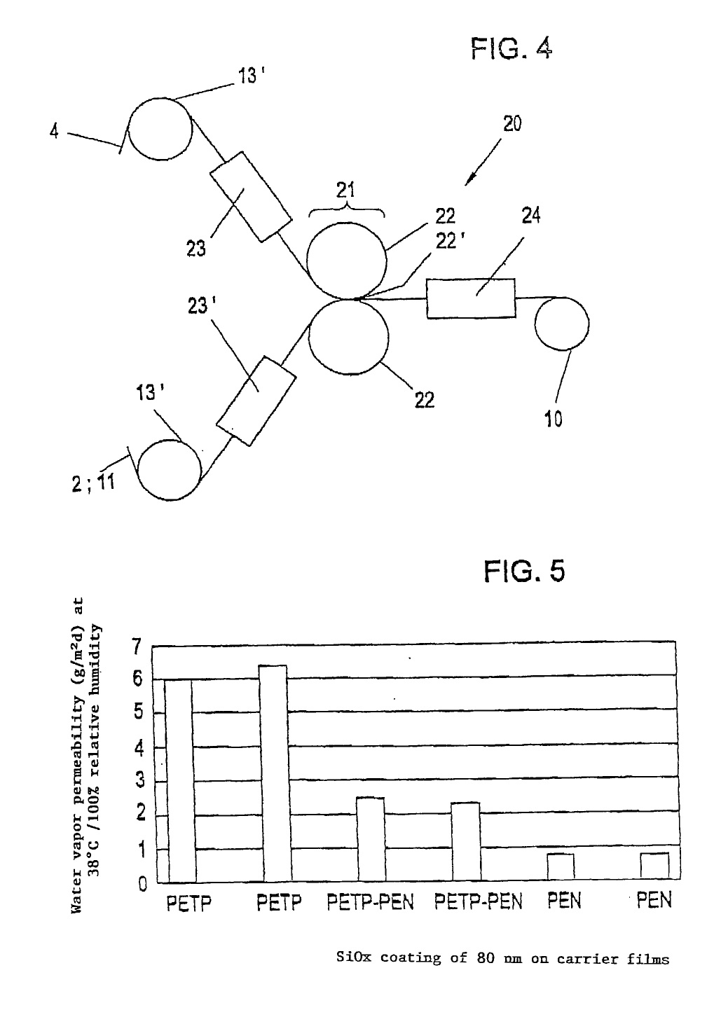

Another process version as claimed in the invention is detailed using the device as shown in FIG. 4. Here, like in the aforementioned process version, the encapsulation material 4 is produced and stored on the delivery roller 13′. On another delivery roller 13′ the thin film solar cell system 2 together with the flexible carrier 11 is stored.

The flexible carrier 11 can be a plastic film or a plastic film composite. For example, polyimide-containing plastics are suited as flexible carriers.

Consequently, the encapsulation material 4 and the thin film solar cell system 2 together with the flexible carrier 11 are supplied to the lamination station. In doing so both material webs in the heating station 23, 23′ are heated to the softening point of the sealing layer 5, i.e. to roughly 70 to 180° C. The lamination station 21 as shown in FIG. 4 is for example a calender roller pair 22. One or both rollers are heated at least to the softening point of the sealing layer 5 in the encapsulation material 4, preferably to 70 to 180° C. In doing so the preheated encapsulation material 4 in the calender roller gap 22′ is applied directly to the thin film solar cell system 2 and due to the contact pressure of the roller of roughly 80 to 400 N/cm (line pressure), pressed to it. Then the composite is hardened in a hardening furnace 24 at temperatures from roughly 120 to 190° C. By means of this lamination step the thin film solar cell system 2 is encapsulated and the photovoltaic thin-film module 10 as shown in FIG. 2 is formed.

By increasing the number of delivery rollers 13′ the use of an additional encapsulation material 4′ is enabled. According to FIG. 2, it is conceivable for the thin film solar cell system 2 to also be jacketed on two sides so that a further improvement with respect to weathering or barrier protection for the solar cell system 2 is ensured.

In summary, it can be stated that by the process as claimed in the invention the encapsulation material 4 and the thin film solar cell system 2 together with the respective carrier are joined to one another by lamination and pressed under pressure and at an elevated temperature such that a weather-resistant photovoltaic thin film module in the form of a composite is formed. The process as claimed in the invention compared to known processes is characterized by a low process duration and energy costs. In addition, in the process which can be easily carried out, a photovoltaic thin film module which is resistant to UV light, water vapor and other weather influences is made available. By choosing the carrier material, for example in the form of plastic films or plastic film composites, flexible properties are imparted to the photovoltaic module in addition.

### Commercial Applicability

The photovoltaic thin film modules produced by the process as claimed in the invention are used for electrical energy generation from sunlight. Their application possibilities are diverse and extend from miniature power installations for emergency telephones or campers via roof and facade systems integrated into buildings as far as large installations and solar power plants.

In applications outside, it has been found that the barrier action of the encapsulation materials relative to water vapor is additionally increased by the oxide layer deposited from the vapor phase on the carrier films of PEN or PETP-PEN coextrudates.

1. Process for producing a photovoltaic thin film module (1, 10) which has a thin film solar cell system (2) which has been applied to carrier materials (3, 11) and which is optionally jacketed on both sides by encapsulation material composites (4, 4′), characterized in that in a lamination step the material web for the encapsulation material composite (4, 4′) consisting of a protective layer (8, 9) and a sealing layer is brought near another material web for the thin film solar cell system (2) and its carrier material (3, 11) in a lamination station such that the sealing layer (5) adjoins the thin film solar cell system (2) and that by increased pressure and optionally increased temperature a composite in the form of a photovoltaic module (1, 10) is formed.

2. Process as claimed in claim 1, wherein lamination is done using one or more calender roller pairs (17, 21).

3. Process as claimed in claim 1 or 2, wherein the photovoltaic thin film module (1, 10) which has been formed is additionally hardened.

4. Process as claimed in one of claims 1 to 3, wherein the carrier material for the thin film solar cell system (2) is a flexible carrier material (11).

5. Process as claimed in claim 4, wherein the flexible carrier material (11) is one based on plastic films or plastic film composites.

6. Process as claimed in claim 4, wherein the flexible carrier material (11) is one based on metal foils or steel strips.

7. Process as claimed in one of claims 1 to 3, wherein the carrier material for the thin film solar cell system (2) is a stiff carrier material (3).

8. Process as claimed in claim 7, wherein the stiff carrier material (3) is glass.

9. Process as claimed in one of claims 1 to 8, wherein in the encapsulation material (4, 4′) there is a barrier layer (9) which consists of a weathering layer (8), an inorganic oxide layer (7) and a carrier layer (6) which is intended for the inorganic oxide layer (7).

10. Process as claimed in claim 9, wherein plastic films or film composites based on polyethylene naphthenate (PEN) or a coextrudate of polyethylene terephthalate (PETP) and polyethylene naphthenate (PEN) are used in the carrier layer (6).

11. Process as claimed in claim 9 or 10, wherein in the barrier layer (9) an inorganic oxide layer (7) consisting of aluminum or silicon in a thickness of 30 to 200 nm is used.

12. Process as claimed in one of claims 1 to 11, wherein the sealing layer (5) is formed from hot melt materials, such as polyamide or thermoplastic elastomers and/or ionomers.
